(19) United States
(12) Patent Application Publication
(10) Pub. No.: US 2024/0321791 A1
(43) Pub. Date: Sep. 26, 2024

(54) SMOOTH COPPER ON PACKAGING SUBSTRATE OUTER LAYERS

(71) Applicant: SKYWORKS SOLUTIONS, INC., Irvine, CA (US)

(72) Inventors: Ki Wook LEE, Irvine, CA (US); Chien Jen WANG, Taoyuan City (TW)

(21) Appl. No.: 18/604,399

(22) Filed: Mar. 13, 2024

Related U.S. Application Data
(60) Provisional application No. 63/454,260, filed on Mar. 23, 2023.

(51) Int. Cl. H01L 23/00

(52) U.S. Cl. CPC H01L 24/05; H01L 24/03; H01L 2224/02215; H01L 2224/03019; H01L 2224/0401; H01L 2224/04042; H01L 2224/05557

(57) ABSTRACT

According to certain aspects, a packaging substrate can include a plurality of layers including an outer layer, and one or more components on a surface of the outer layer. The one or more components can include a radio-frequency circuit, where the radio-frequency circuit is covered by a protective coating configured to reduce surface roughness of the outer layer and not covered by solder resist.

### CROSS-REFERENCE TO RELATED APPLICATION(S)

This application claims the benefit of U.S. Provisional Application No. 63/454,260, filed Mar. 23, 2023, entitled “SMOOTH COPPER ON PACKAGING SUBSTRATE OUTER LAYERS,” which is incorporated herein by reference in its entirety.

### BACKGROUND

### Field

The present disclosure generally relates to substrates, for example, for packaged electronic modules.

### Description of the Related Art

In many electronics applications, integrated circuits and/or circuit elements are implemented as parts of packaged modules. A packaged module typically includes a substrate configured to receive and support a plurality of components such as semiconductor die and/or circuit elements such as discrete passive components.

### SUMMARY

According to some implementations, the present disclosure relates to a packaging substrate. The packaging substrate can include a plurality of layers including an outer layer, and one or more components on a surface of the outer layer, the one or more components including a radio-frequency circuit, the radio-frequency circuit covered by a protective coating configured to reduce surface roughness of the outer layer and not covered by solder resist.

In some examples, the protective coating is an organic solderability preservative (OSP) coating. In other examples, the protective coating is an electroless nickel/electroless palladium/immersion gold (ENEPIG) coating. In some embodiments, the plurality of layers are made of copper. In an example, the wire bond pad protective coating is an electroless nickel/electroless palladium/immersion gold (ENEPIG) coating.

In certain examples, the one or more components include a wire bond pad. The wire bond pad can be covered by a wire bond pad protective coating. In some examples, the one or more components include a flip chip bump pad. The flip chip bump pad can be covered by the protective coating. In some cases, the protective coating can be an organic solderability preservative (OSP) coating.

In some examples, a roughness average of the surface of the outer layer is 0.3-0.4 μm. In some cases, a roughness average of the surface of the outer layer associated with the radio-frequency circuit is 0.3-0.4 μm. In certain examples, a roughness average of the surface of the outer layer is less than or equal to 0.4 μm. In some cases, a roughness average of the surface of the outer layer associated with the radio-frequency circuit is less than or equal to 0.4 μm.

According to certain implementations, the present disclosure relates to a method of forming or implementing a packaging substrate. The method can include forming or providing a plurality of layers including an outer layer, implementing one or more components on a surface of the outer layer, the one or more components including a radio-frequency circuit, the radio-frequency circuit exposed and not covered by solder resist, and applying a protective coating on the radio-frequency circuit, the protective coating configured to reduce surface roughness of the outer layer.

In some examples, the protective coating is an organic solderability preservative (OSP) coating. In other examples, the protective coating is an electroless nickel/electroless palladium/immersion gold (ENEPIG) coating. In some embodiments, the plurality of layers are made of copper. In certain examples, the one or more components can include one or more of: a wire bond pad or a flip chip bump pad.

In certain examples, the method can further include applying a solder resist material on the outer layer, but not covering the radio-frequency circuit. The method can also include applying a selective masking material over the solder resist material for applying a wire bond pad protective coating. In an example, the wire bond pad protective coating is an electroless nickel/electroless palladium/immersion gold (ENEPIG) coating. The method can additionally include applying the wire bond pad protective coating over a wire bond pad. The method may further include removing the selective masking material. The method may also include applying the protective coating over a flip chip bump pad. In some cases, the protective coating is an organic solderability preservative (OSP) coating.

In some examples, a roughness average of the surface of the outer layer is 0.3-0.4 μm. In some cases, a roughness average of the surface of the outer layer associated with the radio-frequency circuit is 0.3-0.4 μm. In certain examples, a roughness average of the surface of the outer layer is less than or equal to 0.4 μm. In some cases, a roughness average of the surface of the outer layer associated with the radio-frequency circuit is less than or equal to 0.4 μm.

According to some implementations, the present disclosure relates to a packaging substrate. The packaging substrate can include a plurality of layers including an outer layer, and one or more components on a surface of the outer layer, the one or more components including a radio-frequency circuit, the radio-frequency circuit exposed and not covered by solder resist.

In some embodiments, the radio-frequency circuit can be covered by a protective coating configured to reduce surface roughness of the outer layer. In some examples, the protective coating is an organic solderability preservative (OSP) coating. In other examples, the protective coating is an electroless nickel/electroless palladium/immersion gold (ENEPIG) coating.

In some examples, a roughness average of the surface of the outer layer is 0.3-0.4 μm. In some cases, a roughness average of the surface of the outer layer associated with the radio-frequency circuit is 0.3-0.4 μm. In certain examples, a roughness average of the surface of the outer layer is less than or equal to 0.4 μm. In some cases, a roughness average of the surface of the outer layer associated with the radio-frequency circuit is less than or equal to 0.4 μm.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 is a diagram of a packaging substrate, in accordance with one or more embodiments.

FIG. 2 is a chart illustrating copper surface roughness relating to various copper treatment techniques, in accordance with one or more embodiments.

FIG. 3 is a chart illustrating peel strength relating to various copper treatments, in accordance with one or more embodiments.

FIG. 4 is a chart illustrating surface morphology relating to various copper treatments, in accordance with one or more embodiments.

FIG. 5 is a block diagram illustrating a side view of a packaging substrate, in accordance with one or more embodiments.

FIG. 6 is a block diagram illustrating a side view of a packaging substrate having one or more features as described herein, in accordance with one or more embodiments.

FIGS. 7A to 7D are block diagrams that show various stages of a process that can be implemented to fabricate a packaging substrate similar to the packaging substrate of FIG. 5, in accordance with one or more embodiments.

FIGS. 8A to 8D are block diagrams that show various stages of a process that can be implemented to fabricate a packaging substrate similar to the packaging substrate of FIG. 6, in accordance with one or more embodiments.

FIG. 9 shows a plan view of an outer layer of a packaging substrate, in accordance with one or more embodiments.

FIG. 10 shows a process that can be implemented to fabricate a packaging substrate including smooth copper outer layers having one or more features as described herein, in accordance with one or more embodiments.

FIG. 11 depicts an example wireless device having one or more advantageous features described herein, in accordance with one or more embodiments.

### DETAILED DESCRIPTION

The headings provided herein, if any, are for convenience only and do not necessarily affect the scope or meaning of the claimed invention.

In many electronics applications including radio-frequency (RF) applications, integrated circuits and/or circuit elements are implemented as parts of packaged modules. A packaged module typically includes a packaging substrate configured to receive and support a plurality of components such as semiconductor die and/or circuit elements such as discrete passive components. For example, one or more components can be mounted on the upper side of the packaging substrate, and an upper overmold can be provided to encapsulate such components. One or more components may also be mounted on the lower side of the packaging substrate, and a lower overmold can be provided to encapsulate such components. In some embodiments, a packaged module can be a dual-sided module.

A packaging substrate can include a plurality of layers. For example, a packaging substrate can include a plurality of conductive layers (e.g., copper layers), with dielectric layers between the conductive layers. The conductive layers can include one or more inner layers as well as one or more outer layers. In many cases, copper on the conductive layers may need to be smoothed, for example, for improved electrical performance. For inner layers, a smooth copper treatment can include applying an organic adhesion promoter (OAP) layer to enhance adhesion between copper and other materials. However, OAP can be material selective and may have poor adhesion for solder mask or solder resist on outer layers. Therefore, applying OAP to an outer layer of a packaging substrate may not provide a desired degree of adhesion. Accordingly, improved smooth copper technology can be provided for outer layers of a packaging substrate, for example, utilizing a solderability preservative coating, such as organic solderability preservative (OSP).

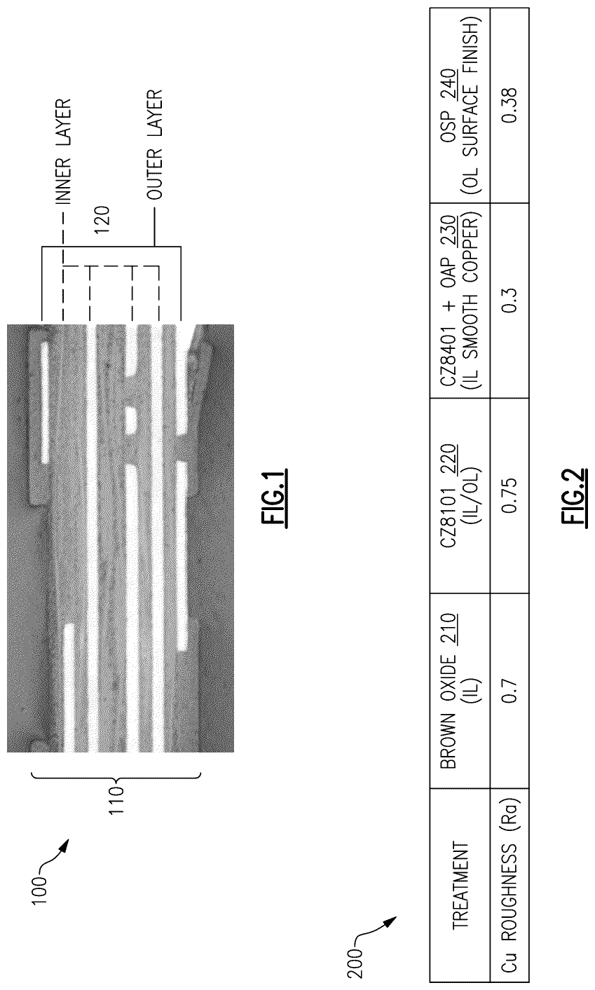

FIG. 1 is a diagram 100 of a packaging substrate 110. For example, the packaging substrate 110 can be a printed circuit board (PCB). The packaging substrate 110 can include a plurality of conductive layers 120. For instance, the layers 120 may be made of copper (Cu). Other materials may be used to form the layers 120 depending on the embodiment. The layers 120 can include one or more inner layers and one or more outer layers. The packaging substrate 110 can also include other layers and features, such as dielectric layers, passive components (such as resistors, capacitors, and inductors), conductor features (such as vias and traces), and a ground plane.

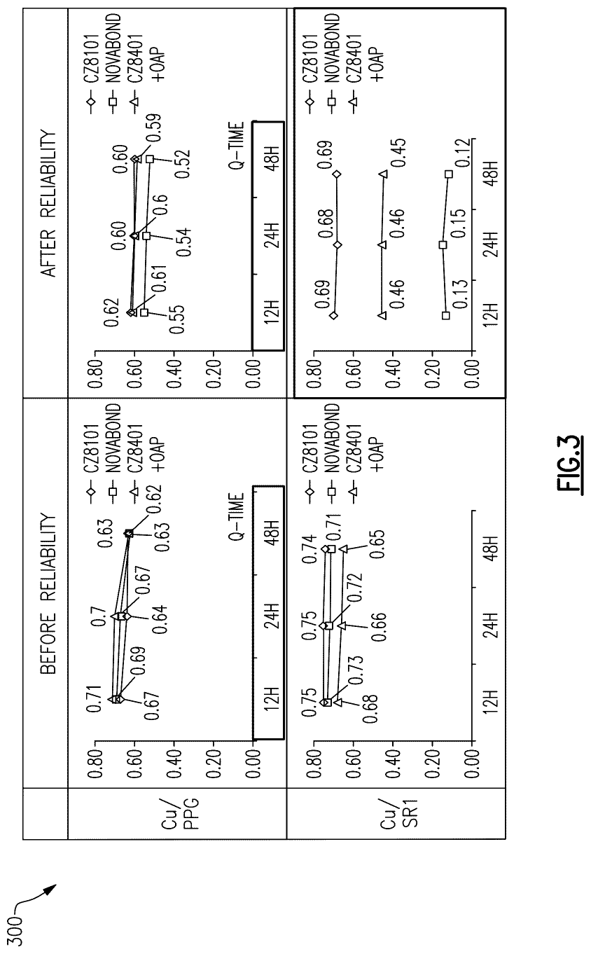

The copper surface of a layer 120 may have a certain level of roughness to promote mechanical adhesion with other materials. However, if the copper surface is too rough, it may affect electrical signal transmission. Accordingly, smooth copper technology can be provided as described herein to reduce copper surface roughness of a copper layer 120 (e.g., an outer layer) of a packaging substrate 110 and improve electrical properties. Smooth copper technology can provide reduction of insertion loss for radio-frequency front-end module (RFFEM) products, for example, at higher working frequencies. Details relating to smooth copper technology are described below, for example, in connection with FIGS. 2-10.

FIG. 2 is a chart 200 illustrating copper surface roughness relating to various copper treatment techniques. For example, copper treatment techniques can include chemical treatments. A treatment technique may be applied to inner layers (ILs), outer layer (OLs), or both inner layers and outer layers of a packaging substrate. In certain cases, a copper treatment technique may roughen copper surface for better mechanical adhesion with other materials, such as dielectric materials. For instance, standard plated copper may not be sufficiently rough for mechanical adhesion and therefore may require some roughening process. In some cases, a copper treatment technique may smooth copper for better electrical performance. A copper treatment technique may be effective for inner layers, outer layers, or both inner layers and outer layers, depending on the technique.

The chart 200 lists several copper treatments and corresponding roughness averages (Ra). Roughness averages are indicated in micrometers or microns (μm). The first treatment 210 is brown oxide, which can be applied to inner layers. The first treatment 210 provides a roughness average of about 0.7 μm. The second treatment 220 is CZ8101, which can be applied to inner layers and outer layers. The second treatment 220 provides a roughness average of about 0.75 μm. The third treatment 230 is CZ8401+OAP, which can be applied to inner layers. The third treatment 230 provides a roughness average of about 0.3 μm. The fourth treatment 240 is OSP, which can be applied to outer layers. The fourth treatment 240 provides a roughness average of about 0.38 μm. The various treatments may be applied to both inner layers and outer layers, but may be effective only for inner layers, only for outer layers, or for both inner layers and outer layers, depending on the treatment.

The third treatment CZ8401+OAP 230 can smooth copper and enhance adhesion between copper and other materials by applying an OAP layer. However, chemical bonding can be material selective. The CZ8401+OAP treatment 230 can have equivalent adhesion to standard packaging substrate dielectric types, but has poor adhesion to solder mask (SM) or solder resist (SR) after thermal. Accordingly, the CZ8401+OAP treatment 230 can work well with inner layers, but may not work well with outer layers of a packaging substrate.

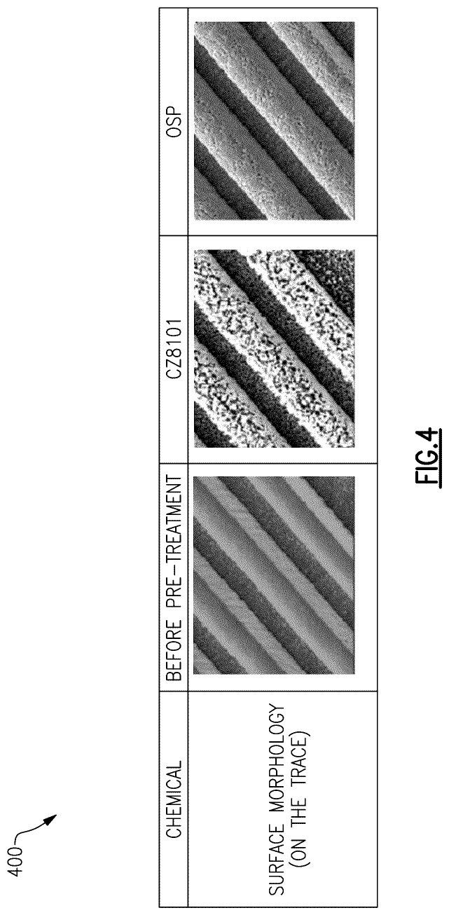

FIG. 3 is a chart 300 illustrating peel strength relating to various copper treatments. For example, copper treatments can include one or more treatments included in the chart 200 in FIG. 2. In the top row, the chart 300 shows peel strength relating to copper and dielectric materials (e.g., Cu/PPG) before reliability and after reliability. As an example, a dielectric material for an inner layer can be prepreg (PPG). In the bottom row, the chart 300 shows peel strength relating to copper and solder resist (e.g., Cu/SR1) before reliability and after reliability. The diamond marker is associated with CZ8101, the second treatment 220 from the chart 200. The triangle marker is associated with CZ8401+OAP, the third treatment 230 from the chart 200. The chart 300 shows data points for 12 hours (hrs), 24 hours, and 48 hours. As can be seen in the right section of the bottom row of the chart 300, peel strength is reduced for Cu/SR after thermal for CZ8401+OAP. Accordingly, the CZ8401+OAP smooth copper treatment may not be optimal for outer layers of a packaging substrate. The square marker is associated with another treatment called Novabond, which can have reduced adhesion compared to CZ8401+OAP.

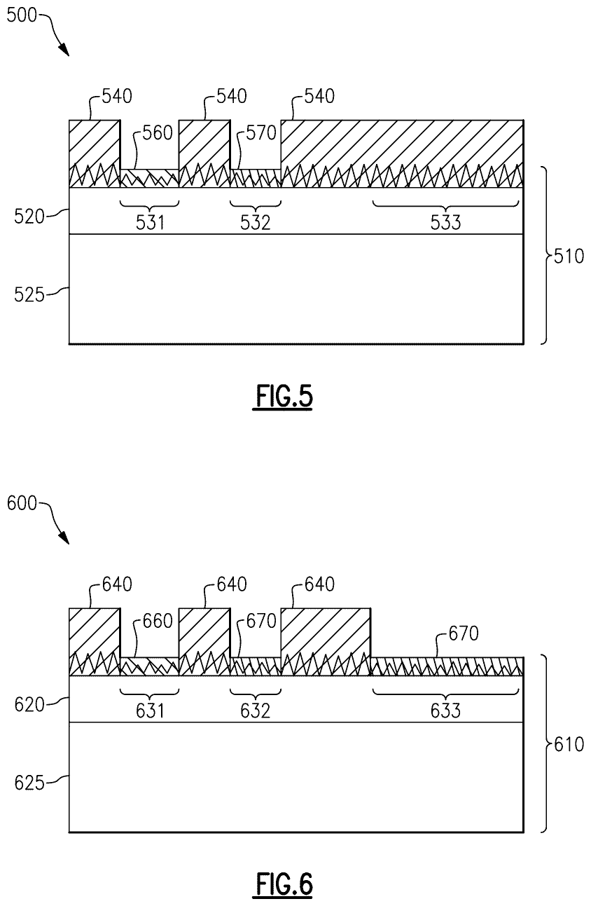

FIG. 4 is a chart 400 illustrating surface morphology relating to various copper treatments. For example, the chart 400 can show surface morphology on traces on an outer layer of a packaging substrate. The first picture (from left to right) can show surface morphology before applying any treatments and/or pre-treatments. The second picture can show surface morphology after applying CZ8101, the second treatment 220 from FIG. 2. The third picture can show surface morphology after applying OSP, the fourth treatment 240 from FIG. 2.

According to certain aspects, OSP may be applied to an outer layer as a surface finish. As shown in FIG. 2, applying OSP can provide average copper roughness similar to the CZ8401+OAP treatment for an inner layer. Accordingly, OSP can be applied to RF critical circuits on an outer layer of a packaging substrate in order to smooth the copper surface. For example, instead of covering the RF critical circuits with solder resist material, the RF critical circuits can be exposed, and OSP can be applied on the exposed RF critical circuits to smooth the copper surface as well as protect the RF critical circuits. Application of OSP can be an existing part of a manufacturing process for a packaging substrate, and therefore, additional steps may not be required to implement a smooth copper technique utilizing OSP.

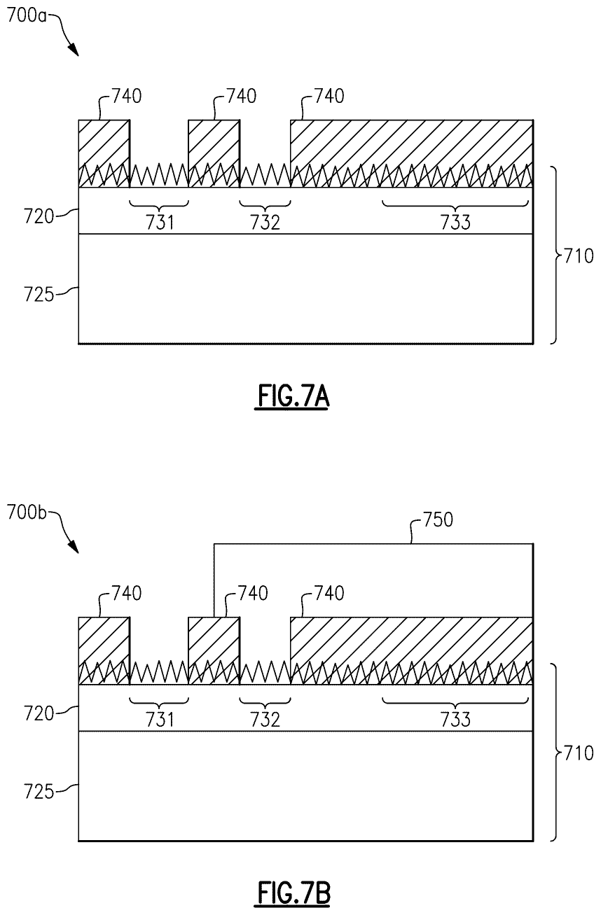

FIG. 5 is a block diagram 500 illustrating a side view of a packaging substrate 510. The packaging substrate 510 can include one or more copper layers. The packaging substrate 510 can also include dielectric layers between copper layers. In the example of FIG. 5, an outer layer 520 of the packaging substrate 510 is shown, with an adjacent dielectric layer 525. The copper surface of the copper layer 520 can have a certain level or degree of roughness. For illustrative purposes, roughness of a copper surface of a copper layer 520 is represented by peaks and/or valleys (e.g., ridges and/or grooves). Heights of peaks and/or depths of valleys may be used to determine a measure of roughness, such as roughness average (Ra). In the example of FIG. 5, higher peaks (or deeper valleys) can represent a rougher surface, and lower peaks (or shallower valleys) can represent a smoother surface.

The surface of the outer layer 520 can include a wire bond pad 531, a flip chip bump pad 532, and an RF critical circuit 533. The surface of the outer layer 520 can include any suitable components as appropriate. According to certain aspects, an RF critical circuit may refer to an RF circuit for which improved electrical properties are desired. An RF critical circuit can include any circuit that passes or processes an RF signal or any related components. The outer layer 520 can be covered by solder mask 540 and expose areas to which other materials may be applied. For example, the wire bond pad 531 and the flip chip bump pad 532 can be exposed for applying a wire bond pad protective coating and a solderability preservative coating, respectively.

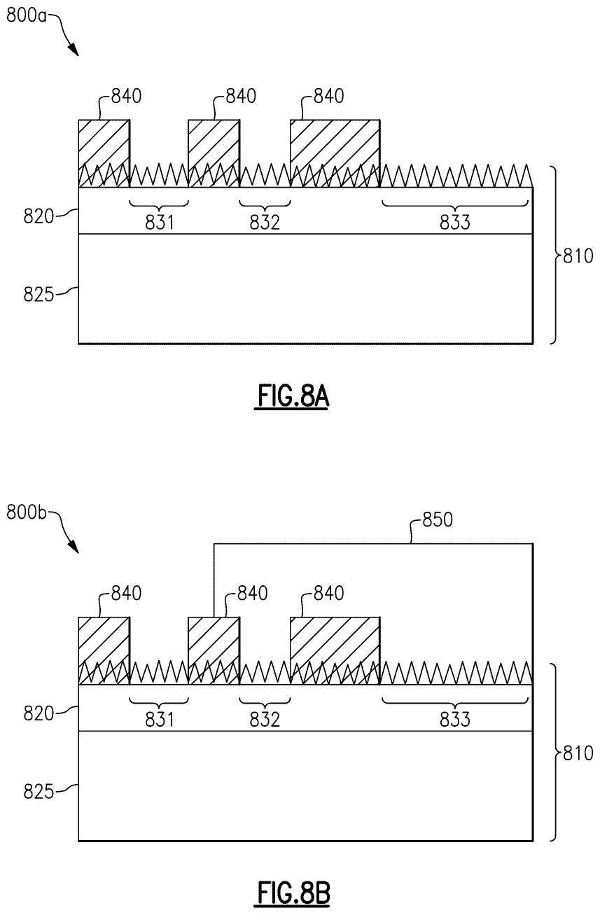

The solder mask 540 can cover the RF critical circuit 533. The wire bond pad 531 can be covered by a wire bond pad protective coating. In the example of FIG. 5, the wire bond pad 531 can be covered by electroless nickel/electroless palladium/immersion gold (ENEPIG) 560. In other embodiments, another suitable protective coating or another suitable material may be applied to the wire bond pad 531. The flip chip bump pad 532 can be covered by a solderability preservative coating. In the example of FIG. 5, the flip chip bump pad 532 can be covered by OSP 570. OSP 570 can smooth the copper surface for the flip chip bump pad 532. In other embodiments, another protective coating or another suitable material may be applied to the flip chip bump pad 532. As shown in FIG. 5, the copper surface for the flip chip bump pad 532 area has lower peaks than the areas covered by the solder mask 540 and therefore has a smoother surface. The RF critical circuit 533 is covered by the solder mask 540, so the copper surface for the RF critical circuit 533 is not smoothed. Accordingly, in the example of FIG. 5, smooth copper technology may not be provided for RF critical circuits. Certain details relating to the packaging substrate 510 are described below in connection with FIGS. 7A-7D.

In certain cases, another layer may be added to a packaging substrate, and input/output pins may be included in the additional layer, such that RF critical circuits may remain in an inner layer. However, adding an additional layer increases the thickness of the packaging substrate and the overall package.

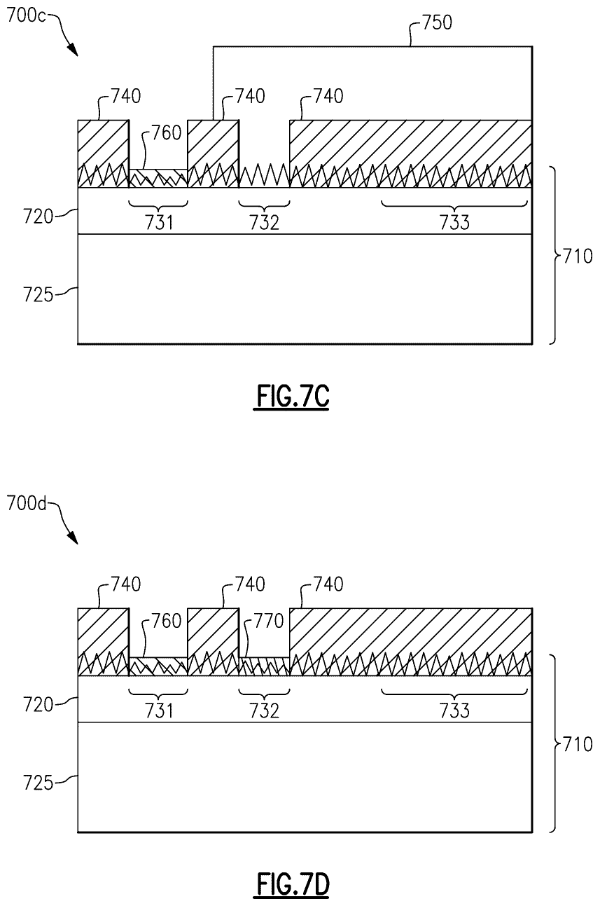

FIG. 6 is a block diagram 600 illustrating a side view of a packaging substrate 610 having one or more features as described herein. Certain aspects relating to the packaging substrate 610 are described in connection with FIGS. 1-5. For example, similar names and/or reference numbers may refer to similar parts or features.

The packaging substrate 610 can include one or more copper layers. The packaging substrate 610 can also include dielectric layers between copper layers. In the example of FIG. 6, an outer layer 620 of the packaging substrate 610 is shown, with an adjacent dielectric layer 625. As in FIG. 5, roughness of a copper surface of a copper layer 620 is represented by peaks and/or valleys (e.g., ridges and/or grooves). Heights of peaks and/or depths of valleys may be used to determine a measure of roughness, such as roughness average (Ra). In the example of FIG. 6, higher peaks (or deeper valleys) can represent a rougher surface, and lower peaks (or shallower valleys) can represent a smoother surface.

The surface of the outer layer 620 can include a wire bond pad 631, a flip chip bump pad 632, and an RF critical circuit 633. The surface of the outer layer 620 can include any suitable components as appropriate. An RF critical circuit can include any circuit that passes or processes an RF signal. According to certain aspects, an RF critical circuit may refer to an RF circuit for which improved electrical properties are desired. An RF critical circuit can include any circuit that passes or processes an RF signal or any related components. The outer layer 620 can be covered by solder mask 640 and expose areas to which other materials may be applied. For example, the wire bond pad 631 can be exposed for applying a wire bond pad protective coating, and the flip chip bump pad 632 and the RF critical circuit 633 can be exposed for applying a solderability preservative coating.

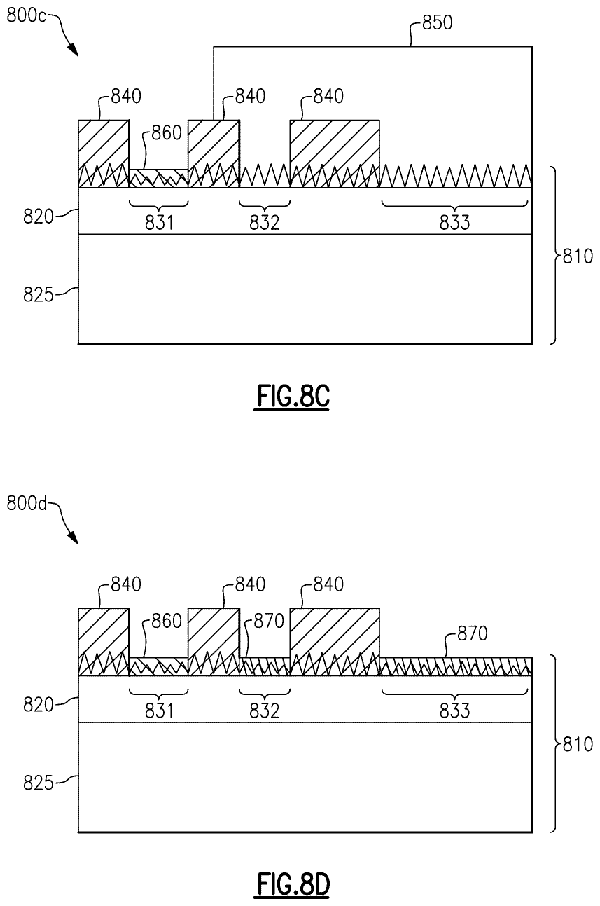

Unlike in the example of FIG. 5, the solder mask 640 does not cover the RF critical circuit 633. The wire bond pad 631 can be covered by a wire bond pad protective coating. In the example of FIG. 6, the wire bond pad 631 can be covered by ENEPIG 660. In other embodiments, another protective coating or another suitable material may be applied to the wire bond pad 631. The flip chip bump pad 632 and the RF critical circuit 633 can be covered by a solderability preservative coating. In the example of FIG. 6, the flip chip bump pad 632 and the RF critical circuit 633 can be covered by OSP 670. OSP 670 can smooth the copper surface for the flip chip bump pad 632 and the RF critical circuit 633. In other embodiments, another protective coating or another suitable material may be applied to the flip chip bump pad 632 and the RF critical circuit 633. As shown in FIG. 6, the flip chip bump pad 632 area and the RF critical circuit 633 area have lower peaks than the areas covered by the solder mask 640 and therefore have a smoother surface. Since the RF critical circuit 633 is covered by OSP 670, the copper surface for the RF critical circuit 633 is smoothed and can provide better electrical signal transmission. Accordingly, in the example of FIG. 6, smooth copper technology can be provided for RF critical circuits and outer layers of a packaging substrate 610. Certain details relating to the packaging substrate 610 are described below in connection with FIGS. 8A-8D.

FIGS. 7A to 7D are block diagrams 700a-700d that show various stages of a process that can be implemented to fabricate a packaging substrate similar to the packaging substrate 510 of FIG. 5. Certain aspects relating to the packaging substrate 710 are described in connection with FIGS. 1-6. For example, similar names and/or reference numbers may refer to similar parts or features.

In FIGS. 7A-7D, a packaging substrate 710 can include one or more copper layers. The packaging substrate 710 can also include dielectric layers between copper layers. In the examples of FIGS. 7A-7D, an outer layer 720 of the packaging substrate 710 is shown, with an adjacent dielectric layer 725. The surface of the outer layer 720 can include a wire bond pad 731, a flip chip bump pad 732, and an RF critical circuit 733. An RF critical circuit can include any circuit that passes or processes an RF signal or related components. The surface of the outer layer 720 can include any suitable components as appropriate.

In FIG. 7A, a solder mask coating can be applied to a rough copper surface of the outer layer 720. For instance, the copper surface may be a rough copper surface without any treatment to the copper surface (e.g., 100% rough copper surface). During the solder mask coating, areas for applying a wire bond pad protective coating, a solderability preservative coating, and/or another material can be exposed. For example, areas for ENEPIG and OSP can be exposed. The RF critical circuit 733 can be covered by solder mask 740.

In FIG. 7B, selective masking can be applied to the packaging substrate 710 in FIG. 7A to expose areas for applying a wire bond pad protective coating or another suitable material, such as ENEPIG. For instance, the wire bond pad 731 can be exposed. The flip chip bump pad 732 and the solder mask 740 adjacent to the flip chip bump pad 732, including the solder mask 740 over the RF critical circuit 733 can be covered by a masking material 750.

In FIG. 7C, a wire bond pad protective coating, such as ENEPIG, can be applied to exposed areas, such as the wire bond pad 731. In certain embodiments, another suitable material other than ENEPIG may be applied. The masking material 750 can be subsequently removed to expose the flip chip bump pad 732.

In FIG. 7D, a solderability preservative coating, such as OSP, can be applied to the flip chip bump pad 732. In certain embodiments, another protective coating or another suitable material can be applied. Accordingly, smooth copper technology can be applied to the flip chip bump pad 732. However, the RF critical circuit 733 does not benefit from the OSP treatment.

FIGS. 8A to 8D are block diagrams 800a-800d that show various stages of a process that can be implemented to fabricate a packaging substrate similar to the packaging substrate 610 of FIG. 6. Certain aspects relating to the packaging substrate 610 are described in connection with FIGS. 1-7D. For example, similar names and/or reference numbers may refer to similar parts or features.

In FIGS. 8A-8D, a packaging substrate 810 can include one or more copper layers. The packaging substrate 810 can also include dielectric layers between copper layers. In the examples of FIGS. 8A-8D, an outer layer 820 of the packaging substrate 810 is shown, with an adjacent dielectric layer 825. The surface of the outer layer 820 can include a wire bond pad 831, a flip chip bump pad 832, and an RF critical circuit 833. An RF critical circuit can include any circuit that passes or processes an RF signal or related components. The surface of the outer layer 820 can include any suitable components as appropriate.

In FIG. 8A, a solder mask coating can be applied to a rough copper surface of the outer layer 820. For instance, the copper surface may be a rough copper surface without any treatment to the copper surface (e.g., 100% rough copper surface). During the solder mask coating, areas for applying a wire bond pad protective coating, a solderability preservative coating, and/or another material can be exposed. For example, areas for ENEPIG and OSP can be exposed. Unlike the example of FIGS. 7A-7D, the RF critical circuit 833 can be exposed without covering by solder mask 840.

In FIG. 8B, selective masking can be applied to the packaging substrate 810 in FIG. 8A to expose areas for applying a wire bond pad protective coating or another suitable material, such as ENEPIG. For instance, the wire bond pad 831 can be exposed. The flip chip bump pad 832, the RF critical circuit 833, and the solder mask 840 adjacent to the flip chip bump pad 832 and the RF critical circuit 833 can be covered by a masking material 850.

In FIG. 8C, a wire bond pad protective coating or another suitable material, such as ENEPIG, can be applied to exposed areas, such as the wire bond pad 831. In certain embodiments, another suitable material other than ENEPIG may be applied. The masking material 850 can be subsequently removed to expose the flip chip bump pad 832 and the RF critical circuit 833.

In FIG. 8D, a solderability preservative coating, such as OSP, can be applied to the flip chip bump pad 832 and the RF critical circuit 833. For instance, the solderability preservative coating may be applied to exposed surfaces of conductive features on the outer layer 820, including conductive pads and circuits. In certain embodiments, another protective coating or another suitable material can be applied. Accordingly, smooth copper technology can be applied to the flip chip bump pad 832 and the RF critical circuit 833. The RF critical circuit 833 can benefit from the OSP treatment and have a smoother copper surface.

Components on the surface of the outer layer 820 can be covered by the same or different materials, depending on the embodiment. In the example of FIGS. 8A-8D, the flip chip bump pad 832 and the RF critical circuit 833 can be covered by the same material. As an example, the flip chip bump pad 832 and the RF critical circuit 833 can be covered by a protective coating, such as a solderability preservative coating. Depending on the embodiment, other components on the outer layer 820 may also be covered with the same material as the flip chip bump pad 832 and the RF critical circuit 833. As an example, the wire bond pad 831, the flip chip bump pad 832, and the RF critical circuit 833 may be covered by ENEPIG. In some embodiments, the flip chip bump pad 832 and the RF critical circuit 833 may be covered by different materials.

Depending on the embodiment, a smooth copper treatment other than a solderability preservative coating (e.g., OSP) can be applied to the RF critical circuit 833 or the outer layer 820. Any suitable surface treatment that can reduce surface roughness may be applied to the outer layer 820 and/or associated components. For instance, any appropriate protective coating or any appropriate material can be applied to the outer layer 820 and/or associated components. Examples can include ENEPIG, electroless nickel/immersion gold (ENIG), nickel/gold (Ni/Au), various types of oxides, etc. In the examples of FIGS. 5-8D, one outer layer is shown for illustrative purposes, but there can be two outer layers as shown in FIG. 1. A smooth copper treatment can be applied to both outer layers. In certain embodiments, the RF critical circuit 833 can remain open and exposed without applying a copper treatment, such as OSP. For example, the exposed copper surface may be smoothed through etching, microetching, etc. Accordingly, the copper surface associated with the RF critical circuit 833 can be smoothed.

A smooth copper treatment can be applied to achieve a desired copper surface roughness. For example, a desired copper roughness can be in relation to the outer layer 820 or a portion of the outer layer 820, such as an area associated with the RF critical circuit 833. As described above, surface roughness may be indicated as a roughness average (Ra). In some embodiments, the roughness average in connection with the outer layer 820 or a portion thereof can be in a range of 0.3 μm to 0.4 μm. In an embodiment, the roughness average can be about 0.38 μm (e.g., as indicated in the chart 200 in FIG. 2 for OSP). In certain embodiments, the roughness average can be less than or equal to 0.4 μm. In some cases, the roughness average can be about 0.31 μm, 0.32 μm, 0.33 μm, 0.34 μm, 0.35 μm, 0.36 μm, 0.37 μm, 0.38 μm, or 0.39 μm. In certain cases, the roughness average can be 0.8 μm or less, 0.75 μm or less, 0.7 μm or less, 0.65 μm or less, 0.6 μm or less, 0.55 μm or less, 0.5 μm or less, 0.45 μm or less, 0.4 μm or less, 0.35 μm or less, etc. Values listed as examples can be approximate values. For instance, the roughness average can approximately or substantially be a value that is listed as an example (e.g., slightly more or less than the value).

In some embodiments, the roughness average may be selected to be comparable to a smooth copper treatment that can be applied to inner layers of the packaging substrate 810 (e.g., CZ8401+OAP). For instance, the roughness average of the outer layer 820 can be selected to be within a specified degree or percentage of the roughness average of the smooth copper treatment that can be applied to inner layers. As an example, the roughness average for the outer layer 820 can be within 0.1 μm or less of the roughness average for one or more inner layers. As another example, the roughness average for the outer layer 820 can be within 30% or less, 25% or less, 20% or less, 15% or less, 10% or less, 5% or less, etc. of the roughness average for one or more inner layers. Values listed as examples can be approximate values. In certain embodiments, the roughness average may be determined in connection with feature sizes (e.g., the RF critical circuit 833).

Surface roughness can be helpful for mechanical properties of the outer layer 820 and associated components, but may not be helpful for electrical properties of the outer layer 820 and associated components. For instance, some surface roughness can increase mechanical adhesion, but affect electrical signal transmission. Accordingly, a level or degree of surface roughness can be determined or achieved such that mechanical properties and electrical properties can be balanced.

In this way, smooth copper technology using a solderability preservative material (e.g., OSP) or other surface treatments can be applied to outer layers of a packaging substrate in order to smooth copper surface and improve electrical performance. Insertion loss of modules using such a packaging substrate can be improved, for example, especially at higher frequencies. By reducing copper surface roughness, an RF critical circuit can be placed on an outer layer of a packaging substrate, without having to add an additional layer to the packaging substrate to place the RF critical circuit within an inner layer. Accordingly, a resulting packaged module can have a reduced thickness and remain more compact. Also, not having to add an additional layer to the packaging substrate can reduce the amount and cost of materials used.

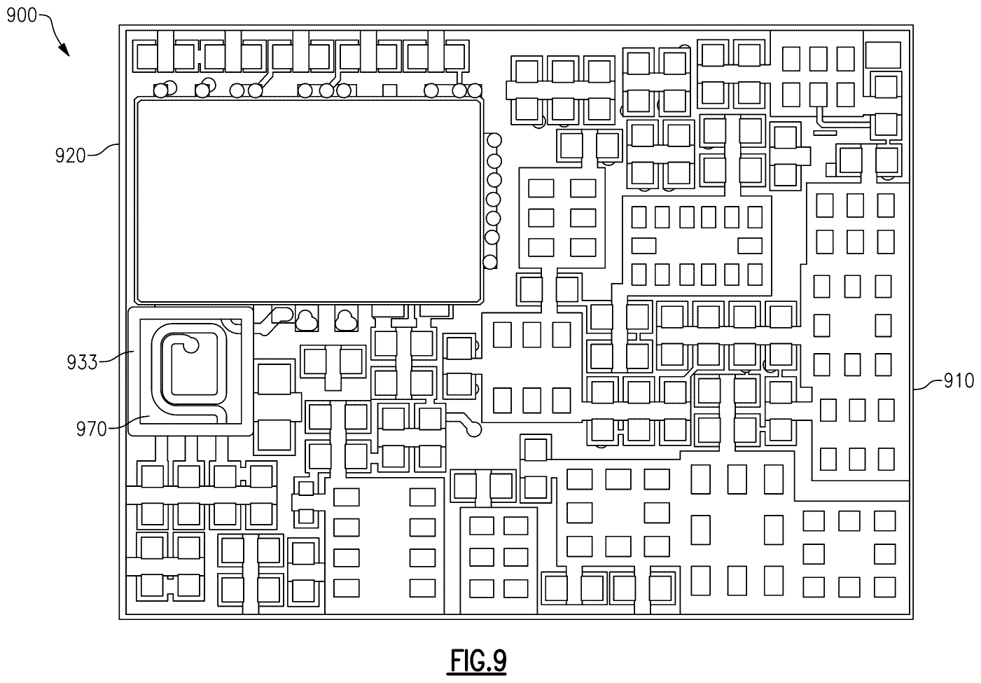

FIG. 9 shows a plan view 900 of an outer layer 920 of a packaging substrate 910. In the example of FIG. 9, an RF critical circuit 933 can include an inductor. For instance, an RF critical circuit 933 can include various types of components, including an inductor, an inductor panel, etc. Instead of covering the RF critical circuit 933 with solder resist, smooth copper technology as described herein can expose the RF critical circuit 933 without covering with solder resist such that the RF critical circuit 933 can be coated with a solderability preservative material, such as OSP 970. The copper surface of the outer layer 920 can be smoothed by the application of the solderability preservative (e.g., OSP), including the area associated with the RF critical circuit 933.

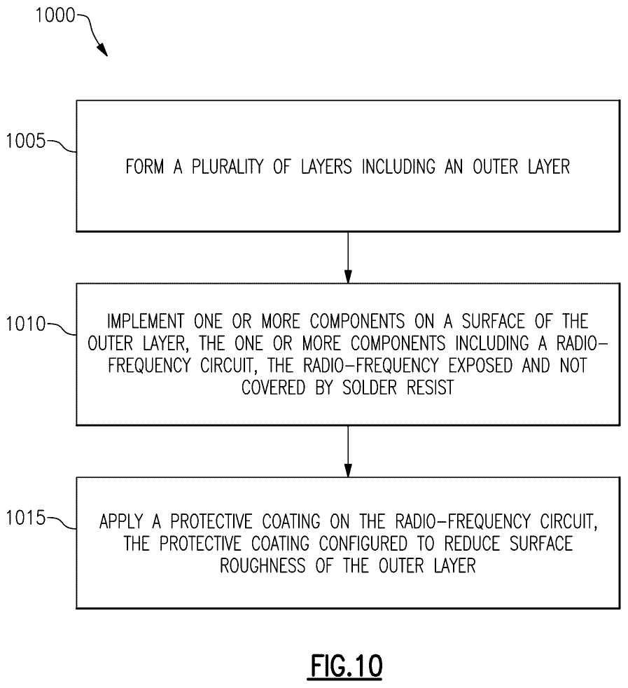

FIG. 10 shows a process 1000 that can be implemented to fabricate a packaging substrate including smooth copper outer layers having one or more features as described herein. Certain details relating to the process 1000 are explained in more detail with respect to FIGS. 1-9. Depending on the embodiment, the process 1000 may include fewer or additional blocks, and the blocks may be performed in an order that is different from illustrated.

At block 1005, the process 1000 can form a plurality of layers including an outer layer. The plurality of layers can be made of copper.

At block 1010, the process 1000 can implement one or more components on a surface of the outer layer, where the one or more components include a radio-frequency circuit, and the radio-frequency circuit is exposed and not covered by solder resist. The one or more components can further include one or more of: a wire bond pad or a flip chip bump pad.

At block 1015, the process 1000 can apply a protective coating on the radio-frequency circuit, where the protective coating is configured to reduce surface roughness of the outer layer. In some embodiments, the protective coating is a solderability preservative coating. For example, the solderability preservative coating is an organic solderability preservative (OSP) coating. In other embodiments, the protective coating is an electroless nickel/electroless palladium/immersion gold (ENEPIG) coating. In some cases, a roughness average of the surface of the outer layer can be between 0.3-0.4 μm. In certain cases, a roughness average of the surface of the outer layer associated with the radio-frequency circuit can be between 0.3-0.4 μm. In some cases, a roughness average of the surface of the outer layer can be less than or equal to 0.4 μm. In certain cases, a roughness average of the surface of the outer layer associated with the radio-frequency circuit can be less than or equal to 0.4 μm.

In some embodiments, the process 1000 can include one or more of the following. For example, the process 1000 can apply a solder resist material on the outer layer, but not cover the radio-frequency circuit. The process 1000 can also apply a selective masking material over the solder resist material for applying a wire bond pad protective coating. The wire bond pad protective coating can be an ENEPIG coating or another suitable material. The process 1000 may further include applying a wire bond pad protective coating (e.g., ENEPIG) over a wire bond pad. The process 1000 can additionally include removing the selective masking material. The process 1000 can apply a protective coating over a flip chip bump pad. For example, the protective coating can be an OSP coating.

A packaging substrate including smooth copper outer layers as described herein can be used to provide packaged modules, such as dual-sided modules. Examples related to upper side and/or lower side configurations of packaged modules, as well as examples related to fabrication methods where a plurality of units can be fabricated in an array format, are described in U.S. Publication No. 2022/0319968, entitled “MODULE HAVING DUAL SIDE MOLD WITH METAL POSTS” and U.S. Publication No. 2018/0096949, entitled “DUAL-SIDED RADIO-FREQUENCY PACKAGE WITH OVERMOLD STRUCTURE,” each of which is hereby expressly incorporated by reference in its entirety. In some embodiments, at least some of the examples provided in U.S. Publication No. 2022/0319968 and U.S. Publication No. 2018/0096949 can utilize packaging substrates including smooth copper outer layers having one or more features as described herein.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

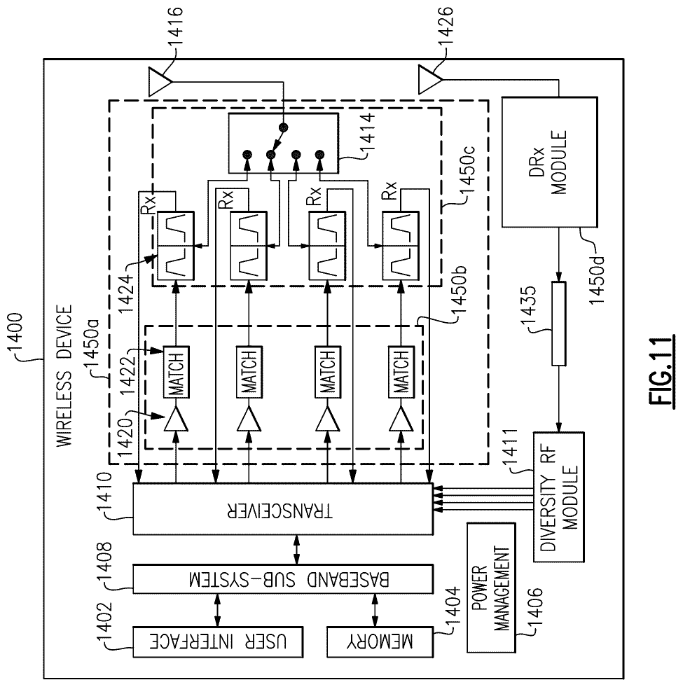

FIG. 11 depicts an example wireless device 1400 having one or more advantageous features described herein. In the example of FIG. 11, an RF module having one or more features as described herein can be implemented in a number of places. For example, an RF module may be implemented as a front-end module (FEM) indicated as 1450a. In another example, an RF module may be implemented as a power amplifier module (PAM) indicated as 1450b. In another example, an RF module may be implemented as an antenna switch module (ASM) indicated as 1450c. In another example, an RF module may be implemented as a diversity receive (DRx) module indicated as 1450d. It will be understood that an RF module having one or more features as described herein can be implemented with other combinations of components.

Referring to FIG. 11, power amplifiers (PAS) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 can also be in communication with a power management component 1406 that is configured to manage power for the operation of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example wireless device 1400, outputs of the PAs 1420 are shown to be matched (via respective match circuits 1422) and routed to their respective duplexers 1424. Such amplified and filtered signals can be routed to a primary antenna 1416 through an antenna switch 1414 for transmission. In some embodiments, the duplexers 1424 can allow transmit and receive operations to be performed simultaneously using a common antenna (e.g., primary antenna 1416). In FIG. 11, received signals are shown to be routed to “Rx” paths that can include, for example, a low-noise amplifier (LNA).

In the example of FIG. 11, the wireless device 1400 also includes the diversity antenna 1426 and the shielded DRx module 1450d that receives signals from the diversity antenna 1426. The shielded DRx module 1450d processes the received signals and transmits the processed signals via a transmission line 1435 to a diversity RF module 1411 that further processes the signal before feeding the signal to the transceiver 1410.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A packaging substrate comprising:
a plurality of layers including an outer layer; and
one or more components on a surface of the outer layer, the one or more components including a radio-frequency circuit, the radio-frequency circuit covered by a protective coating configured to reduce surface roughness of the outer layer and not covered by solder resist.

2. The packaging substrate of claim 1 wherein the protective coating is an organic solderability preservative (OSP) coating.

3. The packaging substrate of claim 1 wherein the protective coating is an electroless nickel/electroless palladium/immersion gold (ENEPIG) coating.

4. The packaging substrate of claim 1 wherein the plurality of layers are made of copper.

5. The packaging substrate of claim 1 wherein the one or more components include a wire bond pad.

6. The packaging substrate of claim 5 wherein the wire bond pad is covered by a wire bond pad protective coating.

7. The packaging substrate of claim 6 wherein the wire bond pad protective coating is an electroless nickel/electroless palladium/immersion gold (ENEPIG) coating.

8. The packaging substrate of claim 1 wherein the one or more components include a flip chip bump pad.

9. The packaging substrate of claim 8 wherein the flip chip bump pad is covered by the protective coating.

10. The packaging substrate of claim 9 wherein the protective coating is an organic solderability preservative (OSP) coating.

11. The packaging substrate of claim 1 wherein a roughness average of the surface of the outer layer is 0.3-0.4 μm.

12. The packaging substrate of claim 1 wherein a roughness average of the surface of the outer layer associated with the radio-frequency circuit is 0.3-0.4 μm.

13. The packaging substrate of claim 1 wherein a roughness average of the surface of the outer layer is less than or equal to 0.4 μm.

14. The packaging substrate of claim 1 wherein a roughness average of the surface of the outer layer associated with the radio-frequency circuit is less than or equal to 0.4 μm.

15. A method of implementing a packaging substrate, the method comprising:
providing a plurality of layers including an outer layer;
implementing one or more components on a surface of the outer layer, the one or more components including a radio-frequency circuit, the radio-frequency circuit exposed and not covered by solder resist; and
applying a protective coating on the radio-frequency circuit, the protective coating configured to reduce surface roughness of the outer layer.

16. The method of claim 15 further comprising applying a solder resist material on the outer layer, but not covering the radio-frequency circuit.

17. The method of claim 16 further comprising applying a selective masking material over the solder resist material for applying a wire bond pad protective coating.

18. The method of claim 17 further comprising applying the wire bond pad protective coating over a wire bond pad.

19. The method of claim 18 further comprising removing the selective masking material.

20. The method of claim 19 further comprising applying the protective coating over a flip chip bump pad.
